(19) United States
(12) Patent Application Publication
(10) Pub. No.: US 2025/0349611 A1
(43) Pub. Date: Nov. 13, 2025

(54) LOW CONTACT RESISTANCE VIAS IN BACKEND INTERCONNECT STRUCTURES

(71) Applicant: Taiwan Semiconductor Manufacturing Co., Ltd., Hsinchu (TW)

(72) Inventors: Ming-Hsing Tsai, Chu-Pei (TW); Ya-Lien Lee, Baoshan Township (TW); Chih-Han Tseng, Tainan City (TW); Kuei-Wen Huang, Hsinchu (TW); Kuan-Hung Ho, Taichung (TW); Ming-Uei Hung, Taichung City (TW); Chih-Cheng Kuo, Taipei City (TW); Yi-An Lai, Hsinchu (TW); Wei-Ting Chen, Taichung City (TW)

(21) Appl. No.: 19/275,681

(22) Filed: Jul. 21, 2025

Related U.S. Application Data
(63) Continuation of application No. 18/619,626, filed on Mar. 28, 2024.
(60) Provisional application No. 63/582,345, filed on Sep. 13, 2023.

(51) Int. Cl. H01L 21/768; H01L 23/522; H10D 30/01; H10D 30/62; H10D 84/01; H10D 84/03

(52) U.S. Cl. CPC H01L 21/76843; H01L 21/76802; H01L 21/76826; H01L 21/76834; H01L 21/76877; H01L 23/5226; H10D 30/024; H10D 30/62; H10D 84/0149; H10D 84/0158; H10D 84/038

(57) ABSTRACT

A method of forming a semiconductor device includes: forming a via in a first dielectric layer disposed over a substrate; forming a second dielectric layer over the first dielectric layer; forming an opening in the second dielectric layer, where the opening exposes an upper surface of the via; selectively forming a capping layer over the upper surface of the via, where the capping layer has a curved upper surface that extends above a first upper surface of the first dielectric layer distal from the substrate; after forming the capping layer, forming a barrier layer in the opening over the capping layer and along sidewalls of the second dielectric layer exposed by the opening; and filling the opening by forming an electrically conductive material over the barrier layer.

### PRIORITY CLAIM AND CROSS-REFERENCE

This application is a continuation of U.S. patent application Ser. No. 18/619,626, filed on Mar. 28, 2024 and entitled “Low Contact Resistance Vias In Backend Interconnect Structures,” which claims the benefit of U.S. Provisional Application No. 63/582,345, filed on Sep. 13, 2023 and entitled “Selective Metal Capping with Inhibitions of Barrier and Liner for Low-contact-resistance Vias in Backend Interconnects,” which applications are hereby incorporated herein by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the sizes of the electronic components continue to shrink in semiconductor manufacturing, challenges arise that need new solutions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7, 8A-8C, 9A and 9B illustrate cross-sectional views of a semiconductor device at various stages of manufacturing, in accordance with an embodiment.

FIGS. 10 and 11 illustrate cross-sectional views of a semiconductor device at various stages of manufacturing, in accordance with another embodiment.

FIG. 12 illustrates a flow chart of a method of forming a semiconductor device, in accordance with an embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Through the discussion herein, unless otherwise specified, the same or similar reference numeral in different figures refer to the same or similar component formed by a same or similar formation method using the same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, in the back-end-of-line (BEOL) processing of a semiconductor device, a capping layer is selectively formed on an underlying via. The capping layer has a curved upper surface to increase the surface area of the interface between the via and a subsequently formed conductive line overlying the via. The increased surface area reduces the contact resistance of the via. In some embodiments, an inhibitor layer is selectively formed on the capping layer. The inhibitor layer impedes the subsequent formation of a barrier layer and a liner layer over the capping layer. As a result, the subsequently formed barrier layer and liner layer have non-uniform thicknesses. For example, portions of the barrier layer/liner layer formed on the capping layer have a smaller thickness, and portions of the barrier layer/liner layer formed on the dielectric layers have a larger thickness. The smaller thickness of the barrier layer/liner layer helps to further reduce the contact resistance, while the larger thickness of the barrier layer/liner layer provides better protection against out-diffusion of the material (e.g., copper) of the conductive line.

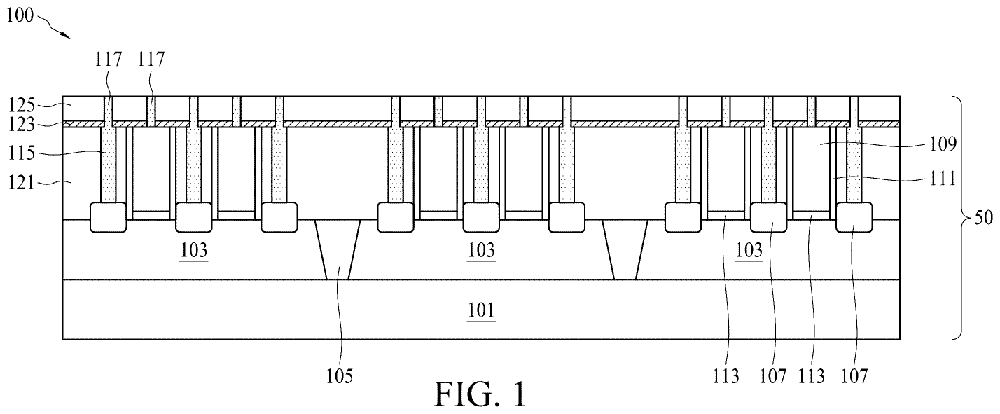

FIGS. 1-9 illustrate cross-sectional views of a semiconductor device 100 at various stages of manufacturing, in accordance with an embodiment. The semiconductor device 100 may be, e.g., a Fin Field-Effect Transistor (FinFET) device.

As illustrated in FIG. 1, the semiconductor device 100 includes a substrate 101. The substrate 101 may be a bulk substrate, such as a silicon substrate, doped or undoped, or an active layer of a semiconductor-on-insulator (SOI) substrate. The substrate 101 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Electrical components, such as transistors, resistors, capacitors, inductors, diodes, or the like, are formed in or on the substrate 101 in the front-end-of-line (FEOL) processing of the semiconductor device. In the example of FIG. 1, semiconductor fins 103 (also referred to as fins) are formed protruding above the substrate 101. Isolation regions 105, such as shallow-trench isolation (STI) regions, are formed between or around the semiconductor fins 103. Gate electrodes 109 and gate dielectric layers 113 are formed over the semiconductor fins 103. Gate spacers 111 are formed along sidewalls of the gate electrodes 109. Source/drain regions 107, such as epitaxial source/drain regions, are formed over the semiconductor fins 103 and on opposing sides of the gate electrodes 109. The FEOL processing for forming electrical component such as FinFETs are known in the art, thus details are not discussed here.

Next, contacts 115 and 117 (e.g., source/drain contacts and gate contacts) are formed in a middle-end-of-line (MEOL) processing to be electrically coupled to respective underlying conductive features (e.g., gate electrodes 109 or source/drain regions 107).

In FIG. 1, a first interlayer dielectric (ILD) layer 121 is formed over the substrate 101 around the gate electrodes 109. The first ILD layer 121 may be formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as chemical vapor deposition (CVD), plasma-enhanced CVD (PECVD), or flowable CVD (FCVD). A planarization process, such as a chemical mechanical planarization (CMP) process, may be performed to planarize the top surface of the first ILD layer 121 such that the top surface of the first ILD layer 121 is level with the top surface of the gate electrode 109.

The contacts 115 (also referred to as source/drain contacts) are formed in the first ILD layer 121, e.g., over and electrically coupled to respective underlying source/drain regions 107. The contact 115 may be formed by forming openings in the first ILD layer 121 (e.g., using photolithography and etching techniques) to expose the underlying source/drain regions 107, and filling the openings with an electrically conductive material, such as tungsten (W), molybdenum (Mo), cobalt (Co), ruthenium (Ru), copper (Cu), or the like.

Next, an etch stop layer (ESL) 123 (e.g. silicon nitride, silicon carbide, silicon oxynitride, or the like) is formed over the first ILD layer 121, and a second ILD layer 125 is formed over the ESL 123. The second ILD layer 125 is formed of a same or similar material as the first ILD layer 121, in some embodiments. The contacts 117 are formed to extend through the second ILD layer 125 and the ESL 123 to be electrically coupled to the underlying conductive features, such as the gate electrodes 109 or the contacts 115. The contacts 117 electrically coupled to respective underlying gate electrodes 109 are also referred to as gate contacts. The contacts 117 may be formed by forming openings in the second ILD layer 125 and filling the openings with an electrically conductive material (e.g., W, Mo, Co, Ru, or Cu). A planarization process, such as CMP, is performed to remove excess portions of the electrically conductive material from the upper surface of the second ILD layer 125 and to achieve a planar upper surface between the contacts 117 and the second ILD layer 125. Note that the structure shown in FIG. 1 is illustrative and non-limiting, variations are possible and are fully intended to be included within the scope of the current disclosure.

Discussion hereinafter focuses on the back-end-of-line (BEOL) processing of the semiconductor device 100, where an interconnect structure is formed over the structure shown in FIG. 1. The interconnect structure comprises a plurality of dielectric layers and conductive features (e.g., vias, conductive lines) formed in the plurality of dielectric layers. The interconnect structure interconnects the underlying electrical components (e.g., transistors) to form functional circuits.

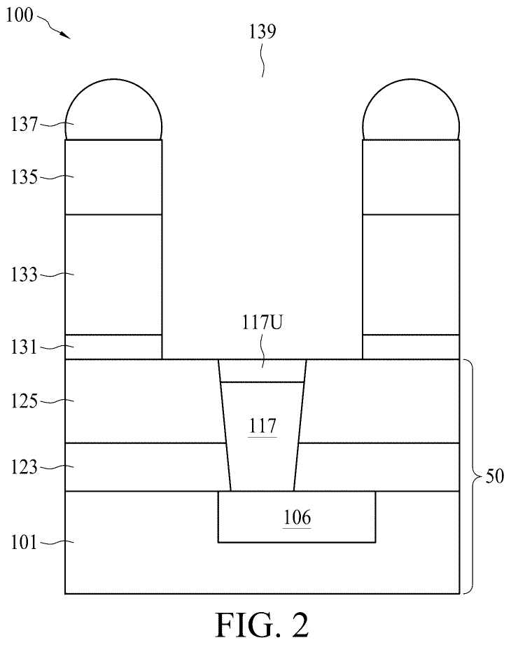

For ease of discussion hereinafter, the structure shown in FIG. 1 is referred to as a device layer 50. In addition, to avoid cluttering, the illustration of the device layer 50 in subsequent figures (see, e.g., FIG. 2) is simplified, and is illustrated as comprising the substrate 101, a transistor 106 (e.g., a FinFET) formed over the substrate 101, the ESL 123, the second ILD layer 125, and a contact 117 (may also be referred to as a via 117) that extends through the second ILD layer 125 and the ESL 123 to be electrically coupled to a conductive region (e.g., the source/drain region 107, or the gate electrode 109) of the transistor 106, with the understanding that the detailed structure of the device layer 50 is the same as or similar to that of FIG. 1.

Referring next to FIG. 2, an ESL 131, a low-K dielectric layer 133, and a dielectric layer 135 are formed successively over the second ILD layer 125 and the via 117. The ESL 131 is formed of aluminum oxide, in an embodiment, although other suitable materials, such as silicon nitride, silicon carbide, silicon oxynitride, combinations thereof, or the like, may also be used. A suitable formation method, such as plasma-enhanced chemical vapor deposition (PECVD), low-pressure CVD (LPCVD), physical vapor deposition (PVD), or the like, may be used to form the ESL 131.

The low-K dielectric layer 133 is formed of a material having a dielectric constant value (K value) smaller than that of silicon oxide. In an embodiment, the low-K dielectric layer 133 is formed of carbon-doped silicon oxide (e.g., SiOC), using a suitable formation method such as CVD, PECVD, or the like. The dielectric layer 135 is formed of a dielectric material different from that of the low-K dielectric layer 133 to provide etching selectivity for subsequent processing. The dielectric layer 135 may be formed of, e.g., silicon oxide or other suitable material, using any suitable formation method.

Next, an opening 139 is formed in the dielectric layer 135, the low-K dielectric layer 133, and the ESL 131 to expose an upper surface of the via 117. To form the opening 139, a hard mask layer 137 is formed over the dielectric layer 135. The hard mask layer 137 is formed of a suitable material, such as tungsten carbide (WC), using a suitable formation method such as CVD, PECVD, or the like. The hard mask layer 137 is then patterned using, e.g., photolithography and etching techniques, to form a patterned hard mask layer 137. Next, an etching process, such as an anisotropic etching process, is performed using the patterned hard mask layer 137 as an etching mask to form the openings 139 and to expose the via 117.

In the example of FIG. 2, an upper portion 117U of the via 117 is oxidized, e.g., by oxygen in the ambient air, and forms an oxide (e.g., tungsten oxide) of the material (e.g., tungsten) of the via 117. Therefore, the upper portion 117U may also be referred to as the oxidized upper portion 117U of the via 117. A thickness of the oxidized upper portion 117U may be, e.g., between about 2.5 nm and about 3.5 nm.

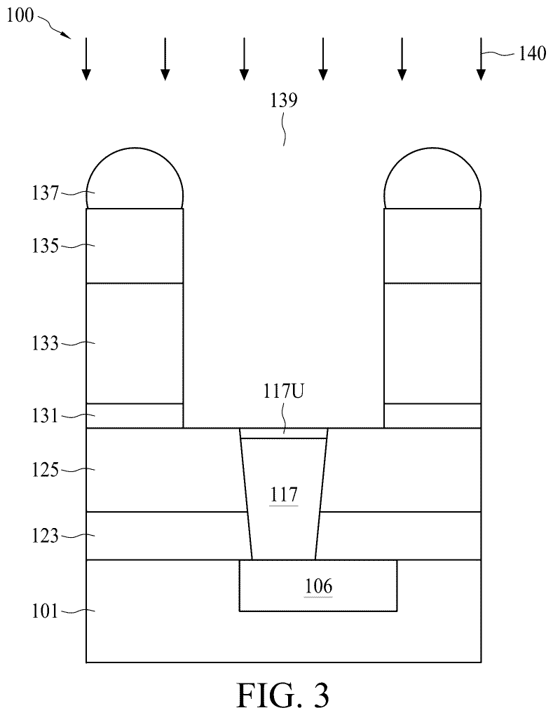

Next, in FIG. 3, a pre-cleaning process 140 is performed to reduce the thickness of the oxidized upper portion 117U of the via 117. In some embodiments, the pre-cleaning process 140 is a plasma cleaning process performed using a remote plasma (e.g., plasma generated at a different processing chamber from the chamber having the semiconductor device 100). The remote plasma may be generated using a gas source (e.g., a gas mixture) of hydrogen gas (e.g., H₂) and a carrier gas such as argon (Ar). A volume percentage of H₂ in the gas source is between about 5% and about 25%, a flow rate of the gas source is between about 200 standard cubic centimeter per minute (sccm) and about 500 sccm, in some embodiments. A power of the RF source for generating the remote plasma is between about 100 W and about 500 W, in some embodiments. The pre-cleaning process may be performed at a temperature between about 300° C. and about 350° C. for a duration between about 25 seconds to about 50 seconds, as an example.

In some embodiments, the hydrogen plasma used in the pre-cleaning process 140 reacts with the oxide in the oxidized upper portion 117U of the via 117, and through a chemical reaction process called reduction process, converts (e.g., reduces) the oxide back into the material (e.g., tungsten) of the via 117. As a result, the thickness of the oxidized upper portion 117U of the via 117 is reduced, e.g., to a thickness between about 1.5 nm and about 2.5 nm. In the example of FIG. 3, a remaining portion of the oxidized upper portion 117U is shown at the top portion of the via 117. In some embodiments, depending on, e.g., the duration of the pre-cleaning process 140, the thickness of the original oxidized upper portion 117U, and/or the parameters of the pre-cleaning process 140, the oxidized upper portion 117U may be completely reduced (e.g., converted) into the material of the via 117. In some embodiments, the reduction process (e.g., the pre-cleaning process 140) does not change the location of the upper surface of the via 117, and therefore, after the pre-cleaning process 140, the upper surface of the via 117 (which may correspond to the upper surface of the oxidized upper portion 117U if the oxidized upper portion 117U is not completed reduced into the material of the via 117) is still level with the upper surface of the second ILD layer 125 distal from the substrate 101. Since the oxidized upper portion 117U of the via 117 may increase the electrical resistance of the via 117, by reducing the thickness of the oxidized upper portion 117U, the electrical performance of the device formed is improved.

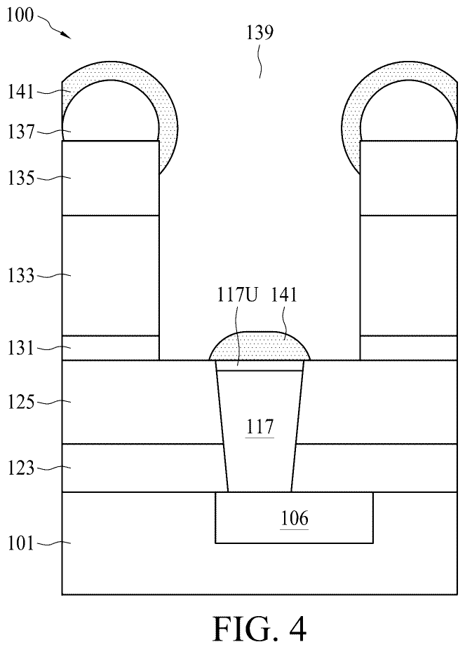

Next, in FIG. 4, a capping layer 141 is selectively formed on the via 117. In some embodiments, the capping layer 141 is formed of a same material as the via 117. For example, the via 117 may be formed of tungsten, and the capping layer 141 is also formed of tungsten. In an embodiment where the via 117 is formed of tungsten, the capping layer 141 is formed by a suitable formation method such as CVD, atomic layer deposition (ALD), or the like, using a tungsten-containing precursor, such as WCl₅ or WF₆. A mixture of the tungsten-containing precursor (e.g., WCl₅ or WF₆) and hydrogen gas may be used in the selective deposition process for the capping layer 141. In embodiments where the via 117 is formed of molybdenum (Mo), a molybdenum-containing precursor, such as MoCl₅, may be used for selectively forming the capping layer 141.

In the example of FIG. 4, the capping layer 141 (e.g., W) is also selectively formed on the hard mask layer 137. In other words, the capping layer 141 is formed on the exposed upper surface of the via 117 and on the exposed surfaces of the hard mask layer 137, and is not formed on other surfaces of the semiconductor device 100. In the illustrated embodiment, the selective formation of the capping layer 141 on the hard mask layer 137 is due to the hard mask layer 137 being formed of a tungsten-containing material, such as tungsten carbide (WC). In the context of the deposition process of the capping layer 141, the material properties of the hard mask layer 137 (e.g. tungsten carbide) is similar to that of the via 117 (e.g., comprising tungsten or tungsten oxide), and since tungsten tends to grow on a tungsten-containing material, the capping layer 141 is selectively formed on the via 117 and the hard mask layer 137 in the example of FIG. 4.

In some embodiments, the deposition rate of the material (e.g., tungsten) of the capping layer 141 on the via 117 and on the hard mask layer 137 is higher than (e.g., twice, five times, or ten times higher) that on the other layers (e.g., 131, 133, and 135) of the semiconductor device 100. Therefore, one or more etching processes, performed using an etchant selective to the material of the capping layer 141, may be performed after the deposition process for the capping layer 141, or performed alternately with the deposition cycles of the deposition process (e.g., an ALD process), such that the surfaces of the other layers (e.g., 131, 133, and 135) of the semiconductor device 100 are free of the capping layer 141 after the deposition process for the capping layer 141 is finished.

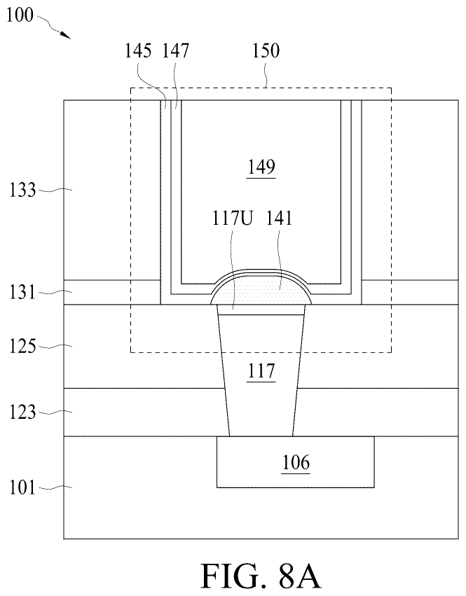

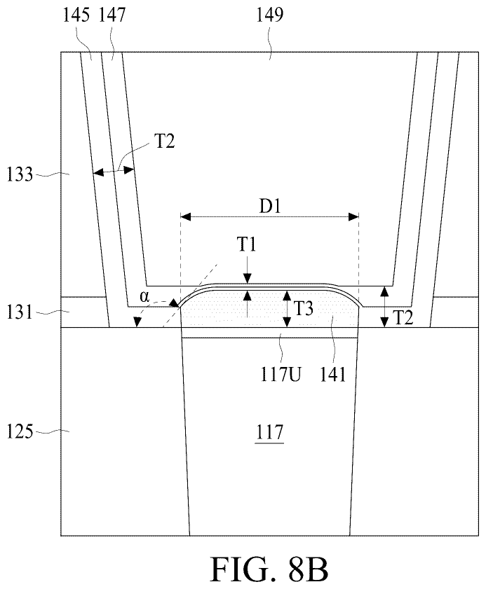

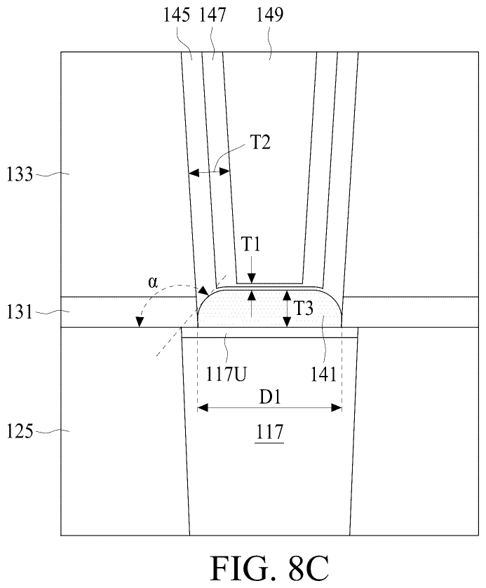

As illustrated in FIG. 4, the capping layer 141 on the via 117 has a lower surface in contact with the via 117 (e.g., in physical contact with the remaining oxidized upper portion 117U of the via 117), and has an upper surface facing away from the via 117. The lower surface of the capping layer 141 is a flat surface, and the upper surface of the capping layer 141 is a curved upper surface (e.g., a convex upper surface). The curved upper surface of the capping layer 141 extends upward away from the substrate 101, and may extend further from the substrate 101 than the lower surface of the low-K dielectric layer 133. The curved upper surface of the capping layer 141 on the via 117 increases the contact surface area between the capping layer 141 and the subsequently formed conductive line 149 (see, e.g., FIG. 8A), and therefore, advantageously reduces the contact resistance of the via 117.

In some embodiments, the capping layer 141 is not formed of the same material (e.g., tungsten) as the via 117, but is formed of an electrically conductive material that has a same or similar lattice constant, crystalline phase, and/or physical/chemical properties as the material of the via 117, where the physical/chemical properties refer to the thermal stability, the melting temperature, the electron affinity, the chemical reactivity (e.g., with materials or chemicals used in subsequent processing, such as C, N, O, F, Cl, or the like), combinations thereof, or the like. The material of the capping layer 141, chosen based on the above criteria, may still allow selective growth of the capping layer 141 as shown in FIG. 4, while allowing for a wide variety of materials to be used for the capping layer 141. Potential benefits of the wider choice for the capping layer 141 may include, e.g., lower cost, higher throughput, better device performance (e.g., lower contact resistance), better compatibility with subsequent BEOL processing, easier integration with existing process flow, as examples.

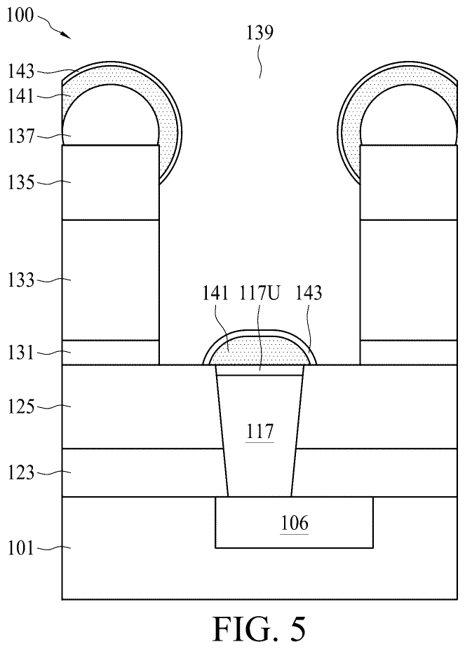

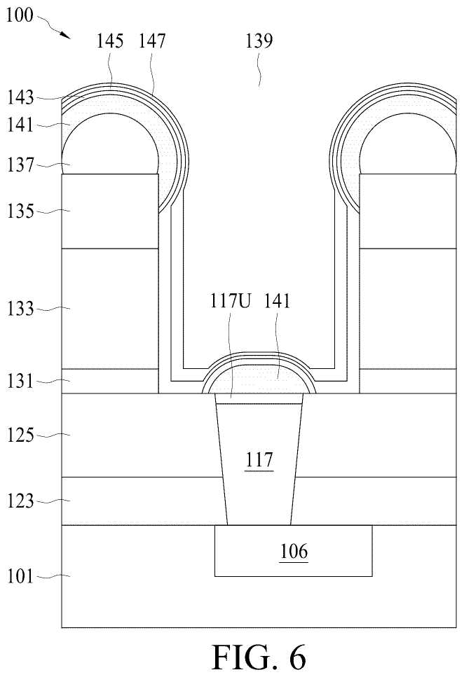

Next, in FIG. 5, an inhibitor layer 143 is selectively formed over the capping layer 141. The inhibitor layer 143 is formed of an inhibitor that impedes the formation (e.g., reduces the deposition rate) of the subsequently formed barrier layer 145 and liner layer 147 (see FIG. 6) on the inhibitor layer 143.

In some embodiments, the inhibitor used to form the inhibitor layer 143 satisfies the following criteria. First, the adsorption of the inhibitor should occur at the surface of via 117 (e.g., W) and not at the surfaces of the dielectric layers (e.g., 131, 133, 135, and 125). Second, the inhibitor should be able to withstand subsequent processing conditions and keep its blocking ability (e.g., ability to impede the formation of the barrier layer and liner layer) during the subsequent deposition of the barrier layer 145 and the liner layer 147. For example, if the deposition of the barrier layer 145 or the liner layer 147 is performed at a high temperature or using a plasma treatment, the inhibitor should not be removed under the high temperature or by the plasma treatment. Last but not the least, the inhibitor should be able to be fully removed from the metal surface (e.g., surface of the via 117) by a subsequent de-blocking process without leaving contamination or causing damage to other layers of the semiconductor device 100.

In some embodiments, the inhibitor layer 143 is formed by soaking the semiconductor device 100 of FIG. 4 in an inhibitor, such as symmetric internal alkyne (SA-03), linear terminal alkyne (SA-02), or linear alkyl silane (SFS-1), as examples. The inhibitor attaches to the exposed metal surfaces of the capping layer 141 by covalent bonds and forms a hydrophobic monolayer (e.g., the inhibitor layer 143) which prevents or impedes the subsequent deposition of the barrier layer 145 and the liner layer 147. In some embodiments, the intrinsic electron affinity and orbital states of the metal surfaces of the capping layer 141 significantly determine the adsorption of the inhibitor. For example, metal with empty orbitals attracts the inhibitor and form covalent bonds with the inhibitors. On the other hand, most dielectric films do not have the empty orbital to attract inhibitors. As a result, the inhibitor layer 143 is selectively formed on the exposed surfaces of the capping layer 141.

Next, in FIG. 6, the barrier layer 145 and the liner layer 147 are formed successively over the semiconductor device 100 of FIG. 5. The barrier layer 145 may be formed of, e.g., tantalum nitride (TaN), tantalum (Ta), or the like, and the liner layer 147 may be formed of, e.g., ruthenium (Ru), cobalt (Co), or the like. A suitable deposition method, such as CVD, PECVD, ALD, or the like, may be used to form each of the barrier layer 145 and the liner layer 147.

As illustrated in FIG. 6, due to the inhibitor layer 143 impedes the formation of the barrier layer 145 and the liner layer 147, the barrier layer 145 and the liner layer 147 are non-conformal layers. In other words, each of the barrier layer 145 and the liner layer 147 has a non-uniform thickness. In particular, the portions of the barrier layer 145 (or the liner layer 147) formed over the inhibitor layer 143 are thinner (e.g., having a smaller thickness) than portions of the barrier layer 145 (or the liner layer 147) formed on the dielectric layers (e.g., 125, 131, 133, and 135). More details of the barrier layer 145 and the liner layer 147 are discussed hereinafter with reference to FIGS. 8B and 8C.

In some embodiments, since the barrier layer 145 and the liner layer 147 have higher electrical resistance than the conductive material (e.g., copper) of the subsequently formed conductive line 149 and the conductive material (e.g., tungsten) of the capping layer 141, reducing the thicknesses of the barrier layer 145 and the liner layer 147 advantageously reduces the electrical resistance at the interface between the conductive line 149 and the via 117.

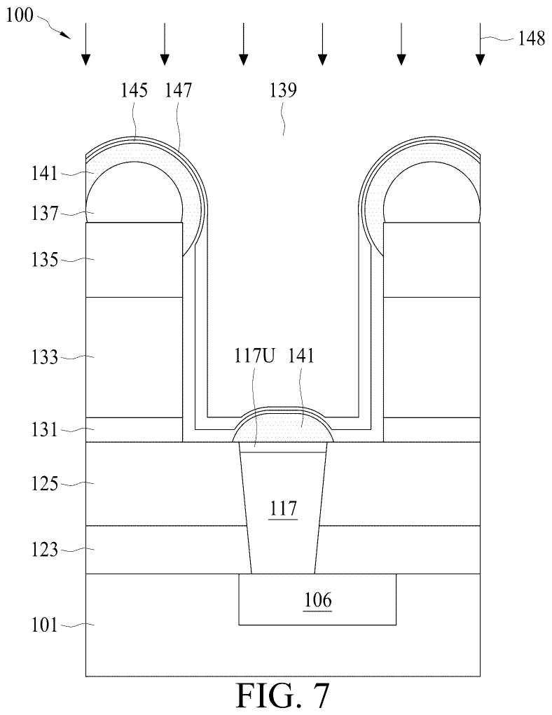

Next, in FIG. 7, a de-blocking process 148 is performed to remove the inhibitor layer 143. In some embodiments, the de-blocking process 148 is a plasma treatment process performed using hydrogen plasma, and therefore, the de-blocking process 148 is also referred to as a hydrogen plasma treatment process. In some embodiments, a gas source (e.g., a mixture of gases) comprising hydrogen gas (H₂) and a carrier gas (e.g., Ar) is ignited into plasma using a capacitively coupled plasma (CCP) system. The flow rate of the gas source is between about 2000 sccm and about 5000 sccm, with a volume percentage of the hydrogen gas in the gas mixture being between about 75% and about 100%. The RF power of the CCP system may be between about 200 W and about 600 W. The hydrogen plasma treatment process may be performed under a pressure between about 1 torr and about 10 torr at a temperature between about 200° C. and about 300° C., as an example.

In some embodiments, the hydrogen plasma reacts with the inhibitor and breaks the inhibitor into smaller volatile fragments, which volatile fragments are then purged away. Therefore, after the hydrogen plasma process is finished, the inhibitor layer 143 is removed (e.g., completely removed) from the semiconductor device 100. In some embodiments, the hydrogen plasma treatment process, when performed with the process parameters describe above, removes the inhibitor layer 143 without damaging the barrier layer 145 and the liner layer 147.

Next, in FIG. 8A, an electrically conductive material is formed over the liner layer 147 to fill the opening 139. The electrically conductive material may be, e.g., copper, titanium, tungsten, aluminum, or the like, formed by a suitable formation method such as PVD, plating (e.g., electroplating or electroless plating), or the like. In an embodiment, the electrically conductive material is copper, and is different from the material (e.g., W) of the via 117. Next, a planarization process, such as CMP, is performed to remove the hard mask layer 137, portions of the capping layer 141 disposed on the hard mask layer 137, the dielectric layer 135, portions of the barrier layer 145/liner layer 147 disposed above the low-K dielectric layer 133, and portions of the electrically conductive material disposed above the low-K dielectric layer 133. The remaining portions of the electrically conductive material in the opening 139 form a conductive line 149. After the planarization process, the conductive line 149, the low-K dielectric layer 133, and the barrier layer 145/liner layer 147 have a coplanar upper surface.

FIG. 8B illustrates a zoomed-in view of an area 150 of FIG. 8A. As illustrated in FIG. 8B, portions of the barrier layer 145 (or the liner layer 147) disposed along the upper surface of the capping layer 141 have a smaller thickness than portions of the barrier layer 145 (or the liner layer 147) disposed along surfaces of the dielectric layers (e.g., 125, 131, and 133). In some embodiments, a total thickness T1 of the portions of the barrier layer 145 and the liner layer 147 along the upper surface of the capping layer 141 (referred to as inhibited barrier layer 145/liner layer 147) is smaller than a total thickness T2 of the portions of the barrier layer 145 and the liner layer 14 along the surfaces of the dielectric layers (e.g., 125, 131, and 133) (also referred to un-inhibited barrier layer 145/liner layer 147). For example, the thickness T1 may be between 0.8 nm and about 1.8 nm, and the thickness T2 may be between 2.0 nm and 3.0 nm. In some embodiments, due to the inhibitor layer 143 impeding the formation of the barrier layer 145 and the liner layer 147, the thickness T1 is between about 40% and about 60% of the thickness T2. Note that without the effect of the inhibitor layer 143, each of the barrier layer 145 and the liner layer 147 may be formed as a conformal layer (e.g., having a substantially uniform thickness), with the thickness of each layer vary within a small percentage, such as between 5% and about 10%, of a target thickness. In contrast, the inhibitor layer 143 in the present disclosure causes a significant reduction in the thickness of the inhibited barrier layer 145/liner layer 147 compared with the thickness of the un-inhibited barrier layer 145/liner layer 147.

In some embodiments, a thickness T3 of the capping layer 141 on the via 117 is between about 2.0 nm and about 5.0 nm. A width D1 of the interface between the capping layer 141 and the barrier layer 145 is between about 10.0 nm and about 15.0 nm. An angle α, measured between the lower surface of the barrier layer 145 and a tangent line of the capping layer 141 contacting the edge of the upper surface of the capping layer 141, is between about 120 degree and about 160 degree.

In some embodiments, the thickness T3 of the capping layer 141 indicates the increase in the contact area and the reduction of the contact resistance, and the range of the thickness T3 should be chosen properly for both performance and yield. For example, if the thickness T3 is too small (e.g., smaller than about 2.0 nm), the reduction of contact resistance may not be significant enough. If the thickness T3 is too large (e.g., larger than about 5.0 nm), it may become difficult for the electrically conductive material to fill the bottom of the opening 139, and the conductive line 149 may not be formed properly, which may result in yield loss. In some embodiments, the ratio between the thickness T1 of the inhibited barrier layer 145/liner layer 147 and the thickness T2 of the un-inhibited barrier layer 145/liner layer 147 correlates with the benefit of contact resistance reduction, and therefore, smaller values and ranges (e.g., between 40% and 60%) may indicate better performance. In some embodiments, the thickness T3 of the capping layer 141 is greater than the thickness T1 of the inhibited barrier layer 145/liner layer 147, which may be advantageous since the capping layer 141 is more electrically conductive that the barrier layer 145/liner layer 147.

In the example of FIG. 8B, the conductive line 149 is wider than the capping layer 141 and the via 117. FIG. 8C illustrates an example where the conductive line 149 is narrower than the capping layer 141 and the via 117. In FIG. 8C, the thickness T1 of the inhibited barrier layer 145/liner layer 147 is between about 0.5 nm and about 1.5 nm, and the thickness T2 of the un-inhibited barrier layer 145/liner layer 147 is between about 1.5 nm and about 2.5 nm. A ratio between the thickness T1 and the thickness T2 in FIG. 8C is between about 30% and about 60%. The thickness T3 is between about 2.0 nm and about 5.0 nm. The width D1 is between about 9.0 nm and about 12.0 nm. Note that in FIG. 8C, the angle α is measured between the sidewall of the barrier layer 145 and a tangent line of the capping layer 141 contacting the edge of the upper surface of the capping layer 141. The angel a is between about 110 degree and about 150 degree.

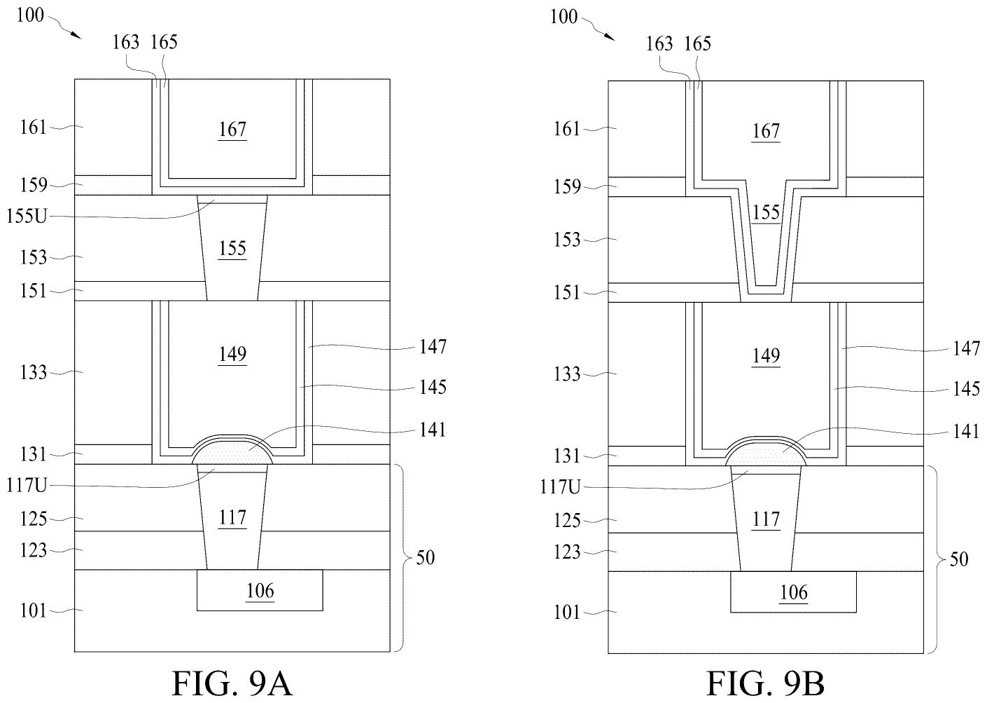

Next, in FIG. 9A, an ESL 151 and a low-K dielectric layer 153 is formed over the low-K dielectric layer 133 and the conductive line 149, and a via 155 is formed to extend through the low-K dielectric layer 153 and the ESL 151 to be electrically coupled to the conductive line 149. The ESL 151, the low-K dielectric layer 153, and the via 155 may be formed of a same or similar material using the same or similar formation method as the ESL 131, the low-K dielectric layer 133, and the via 117, respectively, thus details are not repeated here. FIG. 9A further illustrates an oxidized upper portion 155U of the via 155.

In the illustrated embodiment of FIG. 9A, unlike the via 117, no capping layer 141 is formed on the via 155, and no inhibitor layer 143 is formed on the capping layer 141 (and removed later). This may be because that the contact resistance of the via 117 dominates the resistance of the interconnect structure of semiconductor device 100, and therefore, the capping layer 141 and the inhibitor layer 143 are used to reduce the contact resistance of the via 117. For vias in the interconnect structure (e.g., formed in the BEOL processing), such as the via 155, the capping layer 141 and the inhibitor layer 143 are not used so as to save production cost and to increase throughput. In other embodiments, the via 155 is processed using the same processing steps for the via 117, e.g., using the capping layer 141 and the inhibitor layer 143 to further decrease the electrical resistance of the interconnect structure, in which case the via 155 would have a capping layer 141 formed on top, similar to the capping layer 141 on the via 117. These and other variations are fully intended to be included within the scope of the present disclosure.

Next, an ESL 159 and a low-K dielectric layer 161 are formed over the low-K dielectric layer 153. An opening is formed in the ESL 159 and the low-K dielectric layer 161 to expose the via 155. A barrier layer 163 and a liner layer 165 are formed in the opening, and an electrically conductive material is formed in the opening to form a conductive line 167. The materials and the processing steps for the ESL 159, the low-K dielectric layer 161, the conductive line 167, the barrier layer 163 and the liner layer 165 are the same as or similar to those discussed above, thus details are not repeated. Note that in the example of FIG. 9A, since no capping layer 141 and no inhibitor layer 143 are formed over the via 155, the barrier layer 163 and the liner layer 165 are conformal layers (e.g., each having a substantially uniform thickness).

In FIG. 9A, the via 155 and the conductive line 167 may be formed by two separate single damascene processes. This is, of course, merely a non-limiting example. Other suitable methods, such as a dual damascene process, may also be used to from the via 155 and the conductive line 167 after the ESL 159 and the low-K dielectric layer 161 are formed, as illustrated in FIG. 9B. These and other variations are fully intended to be included within the scope of the present disclosure.

Additional processing may be performed to complete the fabrication of the semiconductor device 100, as skilled artisans readily appreciate. For example, additional layers of dielectric layers and conductive features (e.g., vias, conductive lines) may be formed over the conductive line 167. Under-bump metallurgy (UBM) structures may be formed over a top metal layer of the interconnect structure, and external connectors (e.g., conductive bumps, copper pillars, or the like) may be formed on the UBM structures to allow electrical connection of the semiconductor device 100 with other external devices. Details are not discussed here.

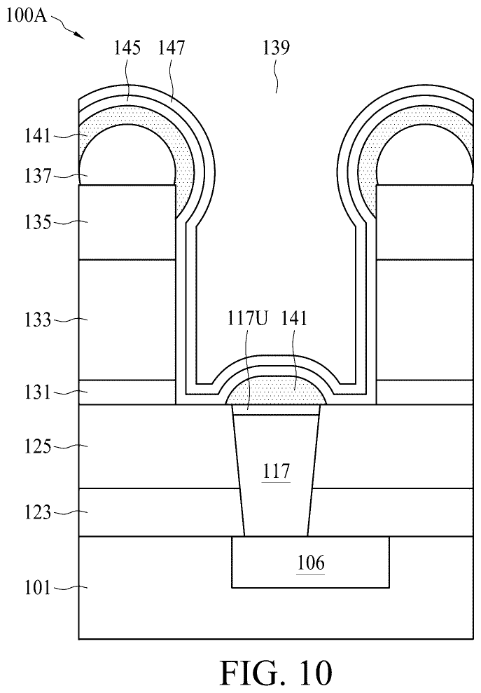

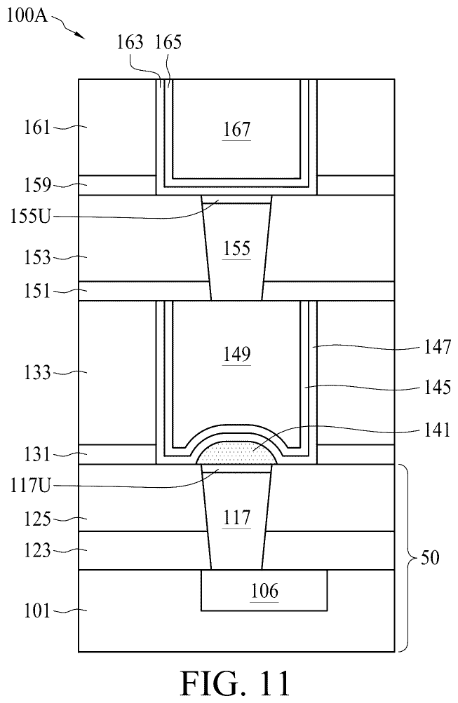

FIGS. 10 and 11 illustrate cross-sectional views of a semiconductor device 100A at various stages of manufacturing, in accordance with another embodiment. The semiconductor device 100A is formed by following similar processing steps as the semiconductor device 100, but without the processing step to form the inhibitor layer 143 and without the de-blocking process 148 to remove the inhibitor layer 143. The processing step illustrated in FIG. 10 follows the processing step of FIG. 4. In other words, FIGS. 1-4, 10, and 11 illustrate various processing steps for forming the semiconductor device 100A.

In FIG. 10, the barrier layer 145 and the liner layer 147 are formed over the structure shown in FIG. 4. Note that since no inhibitor layer 143 is formed on the capping layer 141 prior to the deposition of the barrier layer 145 and the liner layer 147, the barrier layer 145 and the liner layer 147 are formed as conformal layers (e.g., having substantially uniform thickness).

Next, in FIG. 11, the conductive line 149 is formed in the opening 139 by filling the opening 139 with the electrically conductive material, and performing a planarization process, such as CMP. Subsequent processing steps for the via 155, the conductive line 167, the barrier layer 163, the liner layer 165, and the various dielectric layers (e.g., 151, 153, 159, 161) are the same as or similar to those discussed above for the semiconductor device 100, thus details are not repeated.

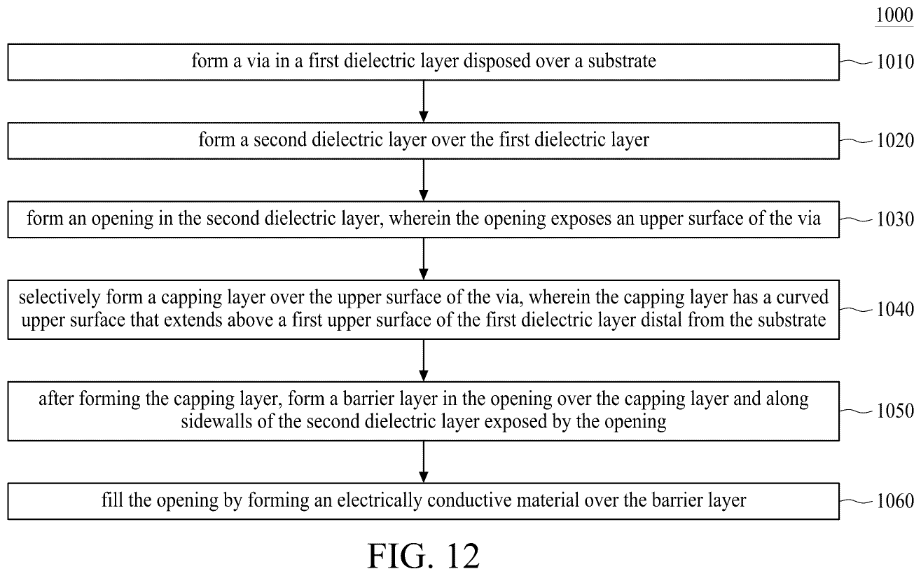

FIG. 12 illustrates a flow chart of a method 1000 of forming a semiconductor device, in accordance with an embodiment. It should be understood that the embodiment method shown in FIG. 12 is merely an example of many possible embodiment methods. One of ordinary skill in the art would recognize many variations, alternatives, and modifications. For example, various steps as illustrated in FIG. 12 may be added, removed, replaced, rearranged, or repeated.

Referring to FIG. 12, at block 1010, a via is formed in a first dielectric layer disposed over a substrate. At block 1020, a second dielectric layer is formed over the first dielectric layer. At block 1030, an opening is formed in the second dielectric layer, wherein the opening exposes an upper surface of the via. At block 1040, a capping layer is selectively formed over the upper surface of the via, wherein the capping layer has a curved upper surface that extends above a first upper surface of the first dielectric layer distal from the substrate. At block 1050, after forming the capping layer, a barrier layer is formed in the opening over the capping layer and along sidewalls of the second dielectric layer exposed by the opening. At block 1060, the opening is filled by forming an electrically conductive material over the barrier layer.

Disclosed embodiments achieve various advantage. For example, the capping layer increases the contact area of the via, thus reduces the contact resistance. The inhibitor layer causes the barrier layer and the liner layer to have a smaller thickness at the interface between the conductive line and the via, and to have a larger thickness along sidewalls of the dielectric layers. The smaller thickness of the barrier layer and the liner layer helps to further reduce the contact resistance, while the larger thickness helps to prevent outer diffusion of the material (e.g. copper) of the conductive line into the dielectric layers. The disclosed method could be easily integrated into existing BEOL processing to achieve improved performance for the device formed.

In an embodiment, a method of forming a semiconductor device includes: forming a via in a first dielectric layer disposed over a substrate; forming a second dielectric layer over the first dielectric layer; forming an opening in the second dielectric layer, wherein the opening exposes an upper surface of the via; selectively forming a capping layer over the upper surface of the via, wherein the capping layer has a curved upper surface that extends above a first upper surface of the first dielectric layer distal from the substrate; after forming the capping layer, forming a barrier layer in the opening over the capping layer and along sidewalls of the second dielectric layer exposed by the opening; and filling the opening by forming an electrically conductive material over the barrier layer. In an embodiment, the upper surface of the via is level with the first upper surface of the first dielectric layer, wherein the curved upper surface of the capping layer is a convex upper surface. In an embodiment, the capping layer is formed of a same material as the via. In an embodiment, the electrically conductive material is different from the material of the via. In an embodiment, the method further includes, before forming the via, forming a transistor over the substrate, wherein the via is formed over the transistor and is formed to be electrically coupled to a conductive region of the transistor. In an embodiment, the first dielectric layer and the second dielectric layer are formed in a middle-end-of-line (MEOL) processing and a back-end-of-line (BEOL) processing of the semiconductor device, respectively. In an embodiment, the method further includes, after selectively forming the capping layer and before forming the barrier layer: selectively forming an inhibitor layer over the capping layer, wherein the inhibitor layer reduces a deposition rate of the barrier layer. In an embodiment, after forming the barrier layer, a first portion of the barrier layer disposed on the capping layer has a first thickness, and a second portion of the barrier layer disposed along the sidewalls of the second dielectric layer has a second thickness, the first thickness being smaller than the second thickness. In an embodiment, the method further includes, after forming the barrier layer and before filling the opening, forming a liner layer in the opening over the barrier layer, wherein a first portion of the liner layer disposed over the capping layer has a third thickness, and a second portion of the liner layer disposed along the sidewalls of the second dielectric layer has a fourth thickness, the third thickness being smaller than the fourth thickness. In an embodiment, the method further includes, after forming the barrier layer and before filling the opening, removing the inhibitor layer. In an embodiment, removing the inhibitor layer comprises performing a plasma treatment process, wherein the plasma treatment process removes the inhibitor layer without removing the barrier layer.

In an embodiment, a method of forming a semiconductor device includes: forming an opening in a second dielectric layer disposed over a first dielectric layer, wherein the first dielectric layer is disposed over a substrate, wherein the opening exposes an upper surface of a via embedded in the first dielectric layer; selectively forming a capping layer on the upper surface of the via; selectively forming an inhibitor layer on the capping layer; after selectively forming the inhibitor layer, lining sidewalls and a bottom of the opening with a barrier layer, wherein the barrier layer is formed to be a non-conformal layer; and filling the opening by forming an electrically conductive material in the opening on the barrier layer. In an embodiment, the method further includes, after the lining and before the filling, removing the inhibitor layer by performing a plasma treatment process, wherein the plasma treatment process removes the inhibitor layer without removing the barrier layer. In an embodiment, the barrier layer has a first portion on the capping layer and has a second portion along sidewalls of the second dielectric layer, wherein the first portion of the barrier layer is thinner than the second portion of the barrier layer. In an embodiment, the method further includes, after the lining and before the filling, forming a liner layer on the barrier layer, wherein the liner layer is formed to be a non-conformal layer, wherein a first portion of the liner layer disposed over the capping layer is thinner than a second portion of the liner layer disposed along the sidewalls of the second dielectric layer. In an embodiment, the upper surface of the via is level with an upper surface of the first dielectric layer distal from the substrate, wherein an upper surface of the capping layer is a convex upper surface and extends further from the substrate than the upper surface of the first dielectric layer.

In an embodiment, a semiconductor device includes: a substrate; a transistor over the substrate; a first dielectric layer over the substrate and the transistor; a via embedded in the first dielectric layer and electrically coupled to a conductive region of the transistor; a capping layer over an upper surface of the via, wherein a lower surface of the capping layer facing the substrate is a flat surface, and an upper surface of the capping layer facing away from the substrate is a convex surface; a second dielectric layer over the first dielectric layer, wherein the upper surface of the capping layer extends further from the substrate than a lower surface of the second dielectric layer facing the substrate; and a conductive line embedded in the second dielectric layer and over the capping layer, wherein the conductive line is electrically coupled to the via through the capping layer. In an embodiment, the semiconductor device further includes a barrier layer extending along sidewalls and a bottom of the conductive line, wherein the barrier layer has a non-uniform thickness. In an embodiment, a first portion of the barrier layer along the upper surface of the capping layer has a first thickness, and a second portion of the barrier layer along the sidewalls of the conductive line has a second thickness larger than the first thickness. In an embodiment, the via and the capping layer are a first electrically conductive material, wherein the conductive line is a second electrically conductive material different from the first electrically conductive material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a via in a first dielectric layer disposed over a substrate;
forming a second dielectric layer over the first dielectric layer;
forming an opening in the second dielectric layer, wherein the opening exposes an upper surface of the via;
selectively forming a capping layer over the upper surface of the via;
selectively forming an inhibitor layer over the capping layer;
forming a barrier layer in the opening over the inhibitor layer and along sidewalls of the second dielectric layer exposed by the opening, wherein the inhibitor layer reduces a deposition rate of the barrier layer;
after forming the barrier layer, removing the inhibitor layer; and
after removing the inhibitor layer, filling the opening with an electrically conductive material.

2. The method of claim 1, wherein the capping layer is formed to have a curved upper surface that extends above a first upper surface of the first dielectric layer distal from the substrate.

3. The method of claim 1, wherein the capping layer and the via are formed of a first metal material.

4. The method of claim 3, wherein the electrically conductive material is a second metal material different from the first metal material.

5. The method of claim 1, wherein after forming the barrier layer, a first portion of the barrier layer along the inhibitor layer has a first thickness, and a second portion of the barrier layer along the sidewalls of the second dielectric layer has a second thickness larger than the first thickness.

6. The method of claim 5, further comprising, after forming the barrier layer and before removing the inhibitor layer, forming a liner layer in the opening over the barrier layer.

7. The method of claim 6, wherein after forming the liner layer, a first portion of the liner layer along the first portion of the barrier layer has a third thickness, and a second portion of the liner layer along the second portion of the barrier layer has a fourth thickness larger than the third thickness.

8. The method of claim 5, wherein removing the inhibitor layer comprises performing a plasma treatment process, wherein after performing the plasma treatment process, the barrier layer remains in the opening and is positioned over the upper surface of the capping layer and along the sidewalls of the second dielectric layer.

9. The method of claim 8, wherein the semiconductor device is positioned in a first processing chamber, wherein the plasma treatment process is a remote plasma process performed using a plasma generated from a second processing chamber different from the first processing chamber.

10. The method of claim 9, wherein the plasma treatment process is performed using a gas source comprising hydrogen gas.

11. A method of forming a semiconductor device, the method comprising:
forming an opening in a second dielectric layer disposed over a first dielectric layer, wherein the first dielectric layer is disposed over a substrate, wherein the opening exposes an upper surface of a via embedded in the first dielectric layer;
selectively forming a capping layer on the upper surface of the via;
after selectively forming the capping layer, lining sidewalls and a bottom of the opening with a barrier layer, wherein the barrier layer is formed to be a non-conformal layer, wherein a first portion of the barrier layer along an upper surface of the capping layer is formed to be thinner than a second portion of the barrier layer along sidewalls of the second dielectric layer; and
filling the opening by forming an electrically conductive material in the opening over the barrier layer.

12. The method of claim 11, further comprising, after selectively forming the capping layer and before the lining, selectively forming an inhibitor layer on the capping layer, wherein the inhibitor layer reduces a deposition rate of the barrier layer.

13. The method of claim 12, further comprising, after the lining and before the filling, removing the inhibitor layer by performing a plasma treatment process.

14. The method of claim 11, wherein selectively forming the capping layer comprises:
depositing the capping layer in the opening, wherein the capping layer is deposited on the upper surface of the via at a faster deposition rate than along the sidewalls of the second dielectric layer; and
after depositing the capping layer, performing an etching process to remove the capping layer from the sidewalls of the second dielectric layer.

15. The method of claim 11, wherein the capping layer and the via are formed of a first metal material, and the electrically conductive material is a second metal material different from the first metal material.

16. The method of claim 11, wherein the upper surface of the via is formed to be level with an upper surface of the first dielectric layer distal from the substrate, wherein an upper surface of the capping layer is formed to be a convex upper surface that extends further from the substrate than the upper surface of the first dielectric layer.

17. A semiconductor device comprising:
a substrate;
a first dielectric layer over the substrate;
a via embedded in the first dielectric layer;
a capping layer over an upper surface of the via distal from the substrate, wherein an upper surface of the capping layer facing away from the substrate is a convex surface;
a second dielectric layer over the first dielectric layer and around the capping layer;
a conductive line embedded in the second dielectric layer and over the capping layer; and
a barrier layer between the conductive line and the second dielectric layer, and between the conductive line and the capping layer, wherein a first portion of the barrier layer along the upper surface of the capping layer has a first thickness, and a second portion of the barrier layer along sidewalls of the second dielectric layer has a second thickness different from the first thickness.

18. The semiconductor device of claim 17, wherein the second thickness is larger than the first thickness.

19. The semiconductor device of claim 18, further comprising a liner layer between the barrier layer and the conductive line, wherein a first portion of the liner layer along the upper surface of the capping layer has a third thickness, and a second portion of the liner layer along the sidewalls of the second dielectric layer has a fourth thickness larger than the third thickness.

20. The semiconductor device of claim 17, wherein the via and the capping layer comprise a first electrically conductive material, wherein the conductive line comprises a second electrically conductive material different from the first electrically conductive material.
